(19) United States
(12) Patent Application Publication
(10) Pub. No.: US 2026/0267436 A1
(43) Pub. Date: Sep. 10, 2026

(54) TOUCH DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Kemeng TONG, Beijing (CN); Fan HE, Beijing (CN); Cong FAN, Beijing (CN); Xiangdan DONG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 19/105,827

(22) PCT Filed: Oct. 31, 2023
(86) PCT No.: PCT/CN2023/128102

§ 371 Date: Feb. 24, 2025

(30) Foreign Application Priority Data
Nov. 24, 2022 (CN) 202211484680.X

(51) Int. Cl. G06F 3/041; G06F 3/044; H10K 59/40

(52) U.S. Cl. CPC G06F 3/04164; G06F 3/0412; G06F 3/0445; G06F 3/0446; H10K 59/40; G06F 2203/04111; G06F 2203/04112

(57) ABSTRACT

The present disclosure relates to a touch display panel, which includes a base substrate and a touch layer. The touch layer includes a plurality of touch traces. Each touch trace includes at least one first extension section, the first extension section is distributed in at least two conductive layers, portions of the first extension section distributed in different conductive layers are connected through a via-hole in a first insulation layer between at least two conductive layers, and a line width of an area of the first extension section provided to correspond to the via-hole is greater than a line width of an area of the first extension section not provided to correspond to the via-hole.

### CROSS-REFERENCE TO RELATED APPLICATIONS

The present disclosure is a U.S. National Stage of International Application No. PCT/CN2023/128102 filed on Oct. 31, 2023, which claims priority to Chinese patent application No. 202211484680.X filed on Nov. 24 2022, entitled “Touch Display Panel And Display Device”, the entire contents of each are incorporated herein by reference.

### TECHNICAL FIELD

The present disclosure relates to the field of display technology, and in particular to a touch display panel and a display device.

### BACKGROUND

With the continuous improvement of the sensory requirement of consumers for screens and the continuous development of display industry technology, users have higher and higher requirements for display quality and overall appearance of display products. Ultra-narrow bezel design (i.e., the display screen has a narrower bezel) may bring users with a better experience. Currently, the bezel of the display screen is relatively wide, and a further narrowing design is required.

The above information disclosed in the background section described herein is only used to enhance the understanding of the background of the present disclosure, and thus it may include information that does not constitute the prior art known to a person skilled in the art.

### SUMMARY

The present disclosure is to provide a touch display panel and a display device.

A first aspect of the present disclosure provides a touch display panel, including:
a base substrate, including a touch area, a first trace area and a binding area, the binding area being located at a side of the touch area in a first direction, and the first trace area being located between the touch area and the binding area; and
a touch layer, provided on a side of the base substrate, and including at least two conductive layers stacked on each other and a first insulation layer provided between two adjacent conductive layers, the touch layer further including a plurality of touch electrodes and a plurality of touch traces, the touch electrodes being distributed in the conductive layers and located in the touch area, one end of the touch trace being connected to the touch electrode, another end of the touch trace being extended to the binding area, at least a portion of the touch trace being located in the first trace area, the touch trace being distributed in the at least two conductive layers, and orthographic projections, on the base substrate, of portions of the touch trace distributed in different conductive layers being at least partially overlapped with each other,
wherein the touch trace includes at least one first extension section extending in a second direction intersecting the first direction, the first extension section is distributed in the at least two conductive layers, portions of the first extension section distributed in different conductive layers are connected through a via-hole in the first insulation layer, and a line width of an area of the first extension section provided to correspond to the via-hole is greater than a line width of an area of the first extension section not provided to correspond to the via-hole.

In an example embodiment of the present disclosure, the at least one first extension section includes a first electrode-connecting section, and the first electrode-connecting section is in contact with and is connected to the touch electrode, and
the first electrode-connecting section includes at least one first via-hole area and at least one first connection area connected to each other, and the first via-hole area is provided to correspond to the via-hole, and a line width of the first via-hole area is greater than a line width of the first connection area.

In an example embodiment of the present disclosure, each of the first via-hole area and the first connection area has a first side close to the touch electrode and a second side away from the touch electrode, and the second side of the first via-hole area is flush with the second side of the first connection area.

In an example embodiment of the present disclosure, a spacing between an outer edge of the first via-hole area and an edge of the via-hole within the first via-hole area is not less than 2.5 μm.

In an example embodiment of the present disclosure, the plurality of touch electrodes includes a plurality of first touch electrodes and a plurality of second touch electrodes, and the plurality of first touch electrodes and the plurality of second touch electrodes are spaced apart and arranged in an array,
the plurality of the first touch electrodes are arranged in the first direction and connected to each other to form a first electrode group, and the plurality of the second touch electrodes are arranged in the second direction and connected to each other to form a second electrode group, and
the touch trace is in contact with and is connected to the first touch electrode group through the first electrode-connecting section.

In an example embodiment of the present disclosure, the at least one first extension section includes at least one first guiding section, and the first guiding section is located in the first trace area and is not in direct contact with the touch electrode, and
the first guiding section includes at least one second via-hole area and at least one second connection area connected to each other, the second via-hole area is provided to correspond to the via-hole, and a line width of the second via-hole area is greater than a line width of the second connection area.

In an example embodiment of the present disclosure, the first guiding sections of different touch traces are spaced apart in the first direction, and the second via-hole areas of the first guiding sections of two adjacent touch traces are staggered.

In an example embodiment of the present disclosure, the at least two conductive layers include a first conductive layer and a second conductive layer, and the second conductive layer is provided on a side of the first conductive layer away from the base substrate,
the first guiding section includes a first sub-section and a second sub-section spaced apart and connected in sequence, the first sub-section is distributed in the first conductive layer, and the second sub-section is distributed in the second conductive layer,
each of the first sub-section and the second sub-section has the second via-hole area and the second connection area, and
orthographic projections, on the base substrate, of the second via-hole area of the first sub-section and the second via-hole area of the second sub-section adjacent to the first sub-section are at least partially overlapped, and orthographic projections, on the base substrate, of the second connection area of the first sub-section and the second connection area of the second sub-section are not overlapped.

In an example embodiment of the present disclosure, the at least two conductive layers include a first conductive layer and a second conductive layer, and the second conductive layer is provided on a side of the first conductive layer away from the base substrate,
the first guiding section includes a first sub-section and a second sub-section, the first sub-section is distributed in the first conductive layer, and the second sub-section is distributed in the second conductive layer,
the first sub-section and the second sub-section are both continuous conductive wires, and
orthographic projections of the first sub-section and the second sub-section on the base substrate are at least partially overlapped.

In an example embodiment of the present disclosure, each of the second via-hole area and the second connection area has a first side close to the touch electrode and a second side away from the touch electrode,
the first side of the second via-hole area and the first side of the second connection area have a first spacing therebetween, the second side of the second via-hole area and the second side of the second connection area have a second spacing therebetween, each of the first spacing and the second spacing is greater than 0, and a difference between the first spacing and the second spacing is not greater than 1 μm.

In an example embodiment of the present disclosure, a spacing between an outer edge of the second via-hole area and an edge of the via-hole within the second via-hole area is not less than 2.5 μm.

In an example embodiment of the present disclosure, the touch trace further includes at least one second extension section extending in a third direction, the second extension section connects two adjacent first extension sections, and the third direction is not parallel to the first direction and the second direction, and
the second extension section is distributed in the at least two conductive layers, portions of the second extension section distributed in different conductive layers are connected through a via-hole in the first insulation layer, and a line width of the second extension section is greater than the line width of the area of the first extension section not provided to correspond to the via-hole.

In an example embodiment of the present disclosure, the line width of the area of the first extension section provided to correspond to the via-hole is not less than 10 μm, and the line width of the area of the first extension section not provided to correspond to the via-hole is greater than or equal to 3 μm and less than 10 μm.

In an example embodiment of the present disclosure, the base substrate further includes a second trace area, and the second trace area is located at at least one side of the touch area in the second direction,
wherein the touch trace further includes at least one third extension section extending in the first direction, the third extension section is distributed in the at least two conductive layers, portions of the third extension section distributed in different conductive layers are connected through a via-hole in the first insulation layer, and a line width of an area of the third extension section provided to correspond to the via-hole is greater than a line width of an area of the third extension section not provided to correspond to the via-hole.

In an example embodiment of the present disclosure, the plurality of touch electrodes includes a plurality of first touch electrodes and a plurality of second touch electrodes, and the plurality of first touch electrodes and the plurality of second touch electrodes are spaced apart and arranged in an array,
the plurality of the first touch electrodes are arranged in the first direction and connected to each other to form a first electrode group, and the plurality of the second touch electrodes are arranged in the second direction and connected to each other to form a second electrode group,
the at least one third extension section includes a second electrode-connecting section, the second electrode-connecting section is located in the second trace area, and the touch trace is in contact with and is connected to the second electrode group through the second electrode-connecting section, and
the second electrode-connecting section includes at least one third via-hole area and at least one third connection area connected to each other, the third via-hole area is provided to correspond to the via-hole, and a line width of the third via-hole area is greater than a line width of the third connection area.

In an example embodiment of the present disclosure, each of the third via-hole area and the third connection area has a first side close to the second electrode group and a second side away from the second electrode group, and the second side of the third via-hole area is flush with the second side of the third connection area.

In an example embodiment of the present disclosure, the at least one third extension section includes at least one second guiding section, the second guiding section is located in the first trace area or the second trace area, and the second guiding section is not in direct contact with the touch electrode,
the second guiding section includes at least one fourth via-hole area and at least one fourth connection area connected to each other, the fourth via-hole area is provided to correspond to the via-hole, and a line width of the fourth via-hole area is greater than a line width of the fourth connection area, and
the second guiding sections of different touch traces are spaced apart in the second direction, and the fourth via-hole areas of the second guiding sections of two adjacent touch traces are staggered.

In an example embodiment of the present disclosure, the touch electrode is mesh-shaped.

In an example embodiment of the present disclosure, the touch display panel further includes a driving circuit layer, a light-emitting layer and an encapsulation layer provided between the base substrate and the touch layer,
the driving circuit layer includes a plurality of pixel circuits, the light-emitting layer is provided on a side of the driving circuit layer away from the base substrate, the light-emitting layer includes a plurality of light-emitting elements, and the pixel circuits are configured to drive the light-emitting elements in one-to-one correspondence to emit light, and
the encapsulation layer covers a side of the light-emitting layer away from the base substrate.

A second aspect of the present disclosure provides a display device including the touch display panel according to the first aspect.

### BRIEF DESCRIPTION OF THE DRAWINGS

The foregoing and other features and advantages of the present disclosure will become more apparent by describing the example embodiments thereof in detail with reference to the accompanying drawings.

FIG. 1 is a schematic structure diagram of a base substrate in an example embodiment of the present disclosure;

FIG. 2 is a schematic planar structure diagram of a touch display panel in an example embodiment of the present disclosure;

FIG. 3 is a schematic structure diagram of the touch trace in area A in FIG. 2;

FIG. 4 is a cross-sectional view of FIG. 3 taken along A1-A2;

FIG. 5 is a schematic structure diagram of the touch trace in area B in FIG. 2;

FIG. 6 is a schematic structure diagram of a first sub-section in FIG. 5;

FIG. 7 is a schematic structure diagram of a second sub-section in FIG. 5;

FIG. 8 is another schematic structure diagram of the touch trace in area B in FIG. 2;

FIG. 9 is yet another schematic structure diagram of the touch trace in area B in FIG. 2;

FIG. 10 is a schematic structure diagram of a first sub-section in FIG. 8;

FIG. 11 is a schematic structure diagram of a second sub-section in FIG. 8;

FIG. 12 is a schematic structure diagram of the touch trace in area C in FIG. 2;

FIG. 13 is a schematic structure diagram of the touch trace in area F in FIG. 2;

FIG. 14 is a schematic structure diagram of the touch trace in area D or E in FIG. 2;

FIG. 15 is a schematic structure diagram of a display module in an example embodiment of the present disclosure; and

FIG. 16 is a cross-sectional view of FIG. 13 taken along B1-B2.

### DETAILED DESCRIPTION

Example embodiments will now be described more fully with reference to the accompanying drawings. However, the example embodiments can be implemented in a variety of forms and should not be construed as being limited to the examples set forth herein; rather, these embodiments are provided so that the present disclosure is more comprehensive and complete and the idea of the example embodiments may be conveyed to a person skilled in the art in a comprehensive manner. The described features, structures, or characteristics may be combined in one or more embodiments in any suitable manner. In the following description, many specific details are provided so as to give a full understanding of the embodiments of the present disclosure.

In the figures, the thicknesses of an area and a layer may be exaggerated for clarity. The same reference numerals denote the same or similar structures in the figures, and thus detailed descriptions thereof will be omitted.

The described features, structures, or characteristics may be combined in one or more embodiments in any suitable manner. In the following description, many specific details are provided so as to give a full understanding of the embodiments of the present disclosure. However, a person skilled in the art may realize that it is possible to practice the technical solution of the present disclosure without one or more of the particular details described or by employing other methods, components, materials, or the like. In other cases, the well-known structures, materials, or operations are not shown or described in detail to avoid obscuring the main technical idea of the present disclosure.

When a structure is “on” another structure, it may mean that the structure is integrally formed on said another structure, or that the structure is “directly” provided on said another structure, or that the structure is “indirectly” provided on said another structure through an additional structure.

The terms “a”, “an” and ‘said’ are used to indicate the presence of one or more elements/components/etc. ; and the terms “comprising/including” and “having” are used to indicate open-ended inclusion and mean that there may be an additional element/component/etc. in addition to those listed. The terms “first”, “second” or the like are used only as marks, and are not intended to limit the number of objects thereof.

Currently, a flexible touch panel is formed by using a flexible mesh layer on cell (FMLOC) method, and the flexible touch panel includes a touch layer that is integrated into a flexible display substrate, and at the top of the flexible touch panel, an organic layer is used to protect the touch layer. For an OLED (Organic Light-Emitting Diode) touch display, a touch trace connects a touch electrode and a peripheral chip. At present, the arrangement of the touch trace occupies a large space in the touch display screen, which cannot satisfy the requirement of a user for a narrower bezel design.

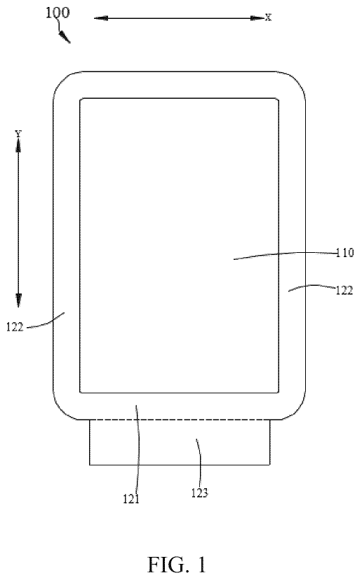

As shown in FIGS. 1, 2, and 15, an implementation of the present disclosure provides a touch display panel, which includes a base substrate 100 and a touch layer 300, the base substrate 100 includes a touch area 110, a first trace area 121 and a binding area 123, the binding area 123 is located at a side of the touch area 110 in a first direction Y, and the first trace area 121 is located between the touch area 110 and the binding area 123. The touch layer 300 is provided on a side of the base substrate 100, the touch layer 300 includes at least two conductive layers stacked on each other and a first insulation layer 303 provided between the conductive layers, the touch layer 300 also includes a plurality of touch electrodes and a plurality of touch traces 306, the touch electrodes are distributed in the conductive layer and are located in the touch area 110, an end of the touch trace 306 is connected to the touch electrode, the other end of the touch trace 306 is extended to the binding area 123, the touch trace 306 is at least partially located in the first trace area 121 and the touch trace 306 is distributed in at least two conductive layers, and orthographic projections of portions of the touch trace 306 distributed in different conductive layers on the base substrate 100 are at least partially overlapped. The touch trace 306 includes at least one first extension section 310 extending in a second direction intersecting the first direction, the first extension section 310 is distributed in the at least two conductive layers, portions of the first extension section 310 distributed in different conductive layers are connected through a via-hole in the first insulation layer 303, and a line width of an area of the first extension section 310 provided to correspond to the via-hole is greater than a line width of an area of the first extension section 310 not provided to correspond to the via-hole.

In the touch display panel provided by the present disclosure, the first extension section 310 of the touch trace 306 is distributed in at least two conductive layers, portions of the first extension section 310 distributed in different conductive layers are connected through a via-hole, and a line width of an area of the first extension section 310 provided to correspond to the via-hole is greater than a line width of an area of the first extension section 310 not provided to correspond to the via-hole. In this way, the space occupied by the touch trace 306 in the first trace area 121 may be reduced, and thus a narrower bezel design of the touch display panel may be achieved.

The components of the touch display panel provided by the implementation of the present disclosure are described in detail below in conjunction with the accompanying drawings.

As shown in FIGS. 1, 2, and 15, the present disclosure provides a touch display panel including a base substrate 100 and a touch layer 300 provided on a side of the base substrate 100.

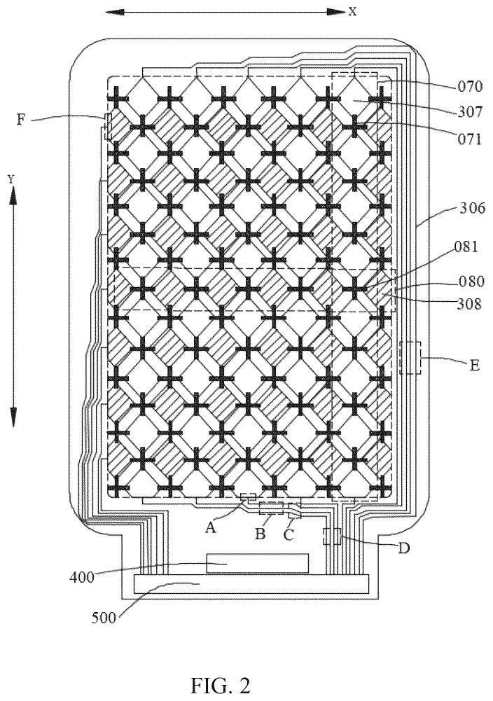

As shown in FIGS. 1 and 2, the base substrate 100 includes a touch area 110, a first trace area 121 and a binding area 123, the binding area 123 is located at a side of the touch area 110 in a first direction Y, and the first trace area 121 is located between the touch area 110 and the binding area 123. The binding area 123 may be used to assemble a touch integrated circuit 400 (also referred to as a touch IC), a flexible printed circuit 500 (FPC) and other structures. In some embodiments, the base substrate 100 further includes a second trace area 122, and the second trace area 122 is located at at least one side of the touch area 110 in the second direction X. Two second trace areas 122 may be provided, which are respectively located at the two sides of the touch area 110 in the second direction X. The second direction X intersects the first direction Y at an angle that may be 85°-90°. Further, the second direction X is substantially perpendicular to the first direction Y. The base substrate 100 may be a glass substrate or a flexible substrate, which is not specifically limited in the present disclosure.

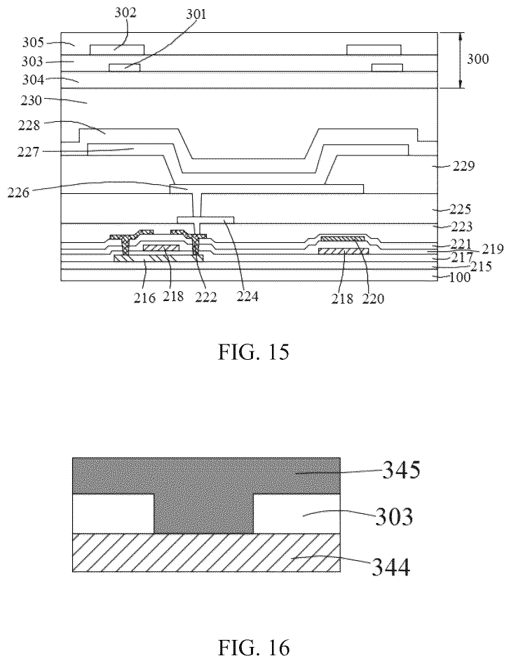

As shown in FIGS. 2 and 15, the touch layer 300 is provided on a side of the base substrate 100 and includes at least two conductive layers stacked on each other and a first insulation layer 303 provided between two adjacent conductive layers, the touch layer 300 further includes a plurality of touch electrodes and a plurality of touch traces 306, the touch electrodes are distributed in the conductive layers and located in the touch area 110, one end of the touch trace 306 is connected to the touch electrode, and the other end of the touch trace 306 is extended to the binding area 123 to be connected to the touch integrated circuit 400 or the flexible printed circuit 500 in the binding area 123.

In some embodiments of the present disclosure, the plurality of touch electrodes includes a plurality of first touch electrodes 307 and a plurality of second touch electrodes 308, and the plurality of first touch electrodes 307 and the plurality of second touch electrodes 308 are spaced apart and arranged in an array. The plurality of the first touch electrodes 307 are arranged in the first direction Y and connected to each other to form a first electrode group 070, and the plurality of the second touch electrodes 308 are arranged in the second direction X and connected to each other to form a second electrode group 080. The first electrode group 070 and the second electrode group 080 are insulated from each other. The orthographic projections of the first touch electrode 307 and the second touch electrode 308 on the base substrate 100 are substantially rhombic, and further, the first touch electrode 307 and the second touch electrode 308 are provided in the same layer, i.e., the first touch electrode 307 and the second touch electrode 308 are formed using the same material and process. The first touch electrode 307 and the second touch electrode 308 are electrode blocks of mesh-shape. The plurality of first touch electrodes 307 and the plurality of second touch electrodes 308 are arranged alternately to form a checkerboard structure. Two adjacent first touch electrodes 307 in the first electrode group 070 may be connected to each other by a first bridge line 071, and two adjacent second touch electrodes 308 in the second electrode group 080 may be connected to each other by a second bridge trace 081. The first bridge trace 071 and the second bridge trace 081 are distributed in different conductive layers, and orthographic projections of the first bridge trace 071 and the second bridge trace 081 on the base substrate 100 are at least partially overlapped.

Further, the at least two conductive layers include a first conductive layer 301 and a second conductive layer 302, and the second conductive layer 302 is provided on a side of the first conductive layer 301 away from the base substrate 100. The first insulation layer 303 is provided between the first conductive layer 301 and the second conductive layer 302. In an embodiment, the first touch electrode 307, the second touch electrode 308, and the first bridge trace 071 are distributed in the first conductive layer 301, and the second bridge trace 081 is distributed in the second conductive layer 302. In another embodiment, the first bridge trace 071 is distributed in the first conductive layer 301, and the first touch electrode 307, the second touch electrode 308, and the second bridge trace 081 are distributed in the first conductive layer 301.

The first electrode group 070 may be a driving electrode group connected to a driving circuit in the touch integrated circuit 400, and the second electrode group 080 may be a detecting electrode group connected to a detecting circuit. Alternatively, the first electrode group 070 is the detecting electrode group connected to the detecting circuit in the touch integrated circuit 400, and the second electrode group 080 is the driving electrode group connected to the driving circuit. Specifically, the first electrode group 070 and the second electrode group 080 may be connected to the respective driving circuit or detecting circuit via the touch trace 306. When a user's finger touches a touchable area of the display panel, the mutual capacitance of the first electrode group 070 and the second electrode group 080 which are insulated from each other and cross with each other at the touch point changes. The driving circuit scans the driving electrode group in the first electrode group 070 and the second electrode group 080 one by one, and reads the signal of each detecting electrode group in the first electrode group 070 and the second electrode group 080 at the same time as one driving electrode group is scanned, and through a scanning round, the coordinate of the touch point can be determined, and the content response corresponding to the touch operation is performed based on the coordinate of the touch point.

As shown in FIGS. 2 to 4, 5, 8, and 9, FIG. 3 is a schematic structure diagram of the touch trace in area A of FIG. 2, and FIGS. 5, 8, and 9 are schematic structure diagrams of the touch trace in area B of FIG. 2 in different embodiments. At least a portion of the touch trace 306 is located in the first trace area 121 and the touch trace 306 is distributed in at least two conductive layers, and orthographic projections, on the base substrate 100, of portions of the touch trace 306 distributed in different conductive layers are at least partially overlapped with each other. The touch trace 306 includes at least one first extension section 310 extending in a second direction X, as shown the portion thereof in areas A and B of FIG. 2. The first extension section 310 is distributed in the at least two conductive layers, portions of the first extension section 310 distributed in different conductive layers are connected through a via-hole in the first insulation, and a line width of an area of the first extension section 310 provided to correspond to the via-hole is greater than a line width of an area of the first extension section 310 not provided to correspond to the via-hole. For example, the line width of the area of the first extension section 310 provided to correspond to the via-hole is not less than 10 μm, and the line width of the area of the first extension section 310 not provided to correspond to the via-hole is greater than or equal to 3 μm and less than 10 μm.

A single touch trace 306 may include a plurality of first extension sections 310, and different first extension sections 310 may be distributed at different locations on the base substrate 100. As shown in FIGS. 2, 5, 8, and 9, in some embodiments of the present disclosure, at least one first extension section 310 includes at least one first guiding section 316, the first guiding section 316 is located in the first trace area 121, the first guiding section 316 is not in direct contact with the touch electrode. The first guiding section 316 includes at least one second via-hole area 317 and at least one second connection area 318 that are connected with each other. The second via-hole area 317 and the second connection area 318 are arranged alternately. The second via-hole area 317 is provided to correspond to the via-hole, and a line width of the second via-hole area 317 is greater than a line width of the second connection area 318. Further, a spacing between an outer edge of the second via-hole area 317 and an edge of the via-hole within the second via-hole area 317 is not less than 2.5 μm to ensure stability of the via-hole connection.

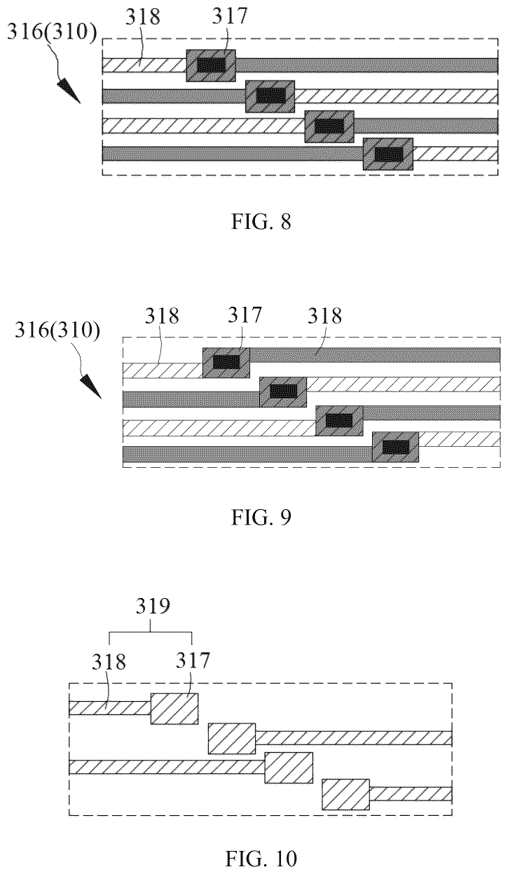

Each of the second via-hole area 317 and the second connection area 318 has a first side close to the touch electrode and a second side away from the touch electrode. There is a first spacing between the first side of the second via-hole area 317 and the first side of the second connection area 318, and there is a second spacing between the second side of the second via-hole area 317 and the second side of the second connection area 318. As shown in FIGS. 5 and 8, in an embodiment, each of the first spacing and the second spacing is greater than 0, and the difference between the first spacing and the second spacing is not greater than 1 μm, preferably the first spacing and the second spacing are substantially equal. As shown in FIG. 9, in another embodiment, for the two second connection areas 318 located on the two sides of the second via-hole area 317 in the second direction X, the spacing between the first side of one second connection area 318 thereof and the first side of the second via-hole area 317 is 0, and the spacing between the second side of the other second connection area 318 thereof and the second side of the second via-hole area 317 is 0.

In a specific embodiment, the first guiding sections 316 of different touch traces 306 are spaced apart in the first direction Y, and the second via-hole areas 317 of the first guiding sections 316 of two adjacent touch traces 306 are staggered. Further, the spacing in the first direction Y between the second via-hole areas 317 of the first guiding sections 316 of the two adjacent touch traces 306 is less than the spacing in the first direction Y between the second connection areas 318 of the first guiding sections of the two adjacent touch traces 306. For example, if the spacing in the first direction Y between the second connection areas 318 of the first guiding sections 316 of the two adjacent touch traces 306 is 3 μm, the spacing in the first direction Y between the second via-hole areas 317 of the first guiding sections 316 of the two adjacent touch traces 306 may be less than 3 μm because the second via-hole areas 317 are staggered, which is conducive to reducing the space occupied by the arrangement of the plurality of touch traces 306 in the first direction Y and thus reducing the width of the first trace area 121, thereby achieving a narrower bezel design.

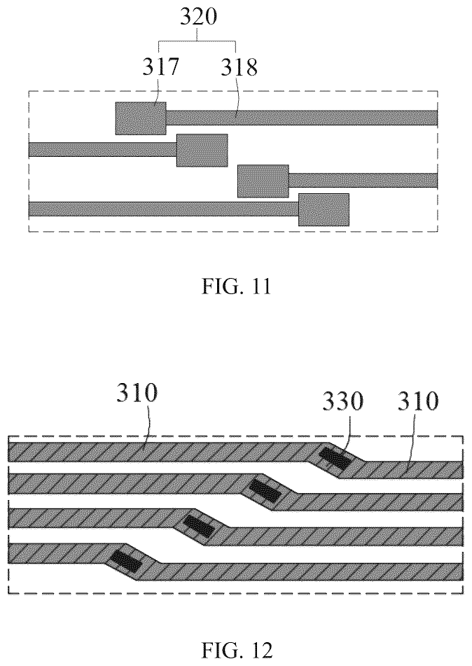

As shown in FIGS. 8 to 11, in some embodiments of the present disclosure, the first guiding section 316 includes a first sub-section 319 and a second sub-section 320 spaced apart and connected in sequence, the first sub-section 319 is distributed in the first conductive layer 301, and the second sub-section 320 is distributed in the second conductive layer 302. Each of the first sub-section 319 and the second sub-section 320 has a second via-hole area 317 and a second connection area 318. An orthographic projection of the second via-hole area 317 of the first sub-section 319 on the base substrate 100 is at least partially overlapped with an orthographic projection of the second via-hole area 317 of the adjacent second sub-section 320 on the base substrate 100, and an orthographic projection of the second connection area 318 of the first sub-section 319 on the base substrate 100 is not overlapped with an orthographic projection of the second connection area 318 of the second sub-section 320 on the base substrate 100. That is, the first guiding section 316 is formed by alternately connecting the first sub-section 319 and the second sub-section 320 in their extension directions. Further, this structure in which different sub-sections located in different conductive layers are alternately connected can be applied to the entire touch trace 306, i.e., each touch trace 306 is formed by alternately connecting different sub-sections located in different conductive layers.

Further, in the present disclosure, the material of each of the first conductive layer 301 and the second conductive layer 302 includes titanium (Ti) and aluminium (Al), and the first conductive layer 301 and the second conductive layer 302 are a multi-layer lamination structure, specifically a titanium (Ti)-aluminium (Al)-titanium (Ti) structure, i.e., the first conductive layer 301 and the second conductive layer 302 are formed by laminating a titanium (Ti) metal layer, an aluminium (Al) metal layer, and a titanium (Ti) metal layer. The thicknesses of the first conductive layer 301 and the second conductive layer 302 are different, and according to actual needs, the thickness of the first conductive layer 301 may be greater than the thickness of the second conductive layer 302, or the thickness of the second conductive layer 302 may be greater than the thickness of the first conductive layer 301. When the touch trace 306 is formed by connecting different sub-sections located in different conductive layers alternately, it may be conducive to reducing the resistance difference between the touch traces 306, and reducing the process difficulty of compensating the resistance of the touch trace 306.

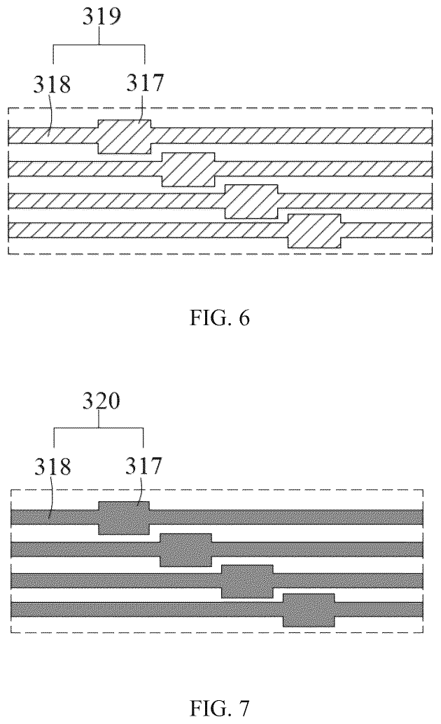

As shown in FIGS. 5 to 7, in some other embodiments of the present disclosure, the first guiding section 316 includes a first sub-section 319 and a second sub-section 320, the first sub-section 319 is distributed in the first conductive layer 301, and the second sub-section 320 is distributed in the second conductive layer 302. Each of the first sub-section 319 and the second sub-section 320 is a continuous conductive line. Orthographic projections on the base substrate 100 of the first sub-section 319 and the second sub-section 320 are at least partially overlapped. Each of the first sub-section 319 and the second sub-section 320 has a second via-hole area 317 and a second connection area 318. An orthographic projection of the second via-hole area 317 of the first sub-section 319 on the base substrate 100 is at least partially overlapped with an orthographic projection of the second via-hole area 317 of the adjacent second sub-section 320 on the base substrate 100, and an orthographic projection of the second connection area 318 of the first sub-section 319 on the base substrate 100 is at least partially overlapped with an orthographic projection of the second connection area 318 of the second sub-section 320 on the base substrate 100 is overlapped. That is, the first guiding section 316 is formed of a combination of consecutive conductive wires located in different conductive layers. Further, in this embodiment, the touch trace 306 is also formed by a combination of successive conductive lines located in different conductive layers, which may reduce the resistance of the touch trace 306 and reduce the power consumption.

As shown in FIGS. 2 and 12, FIG. 12 is a schematic structure diagram of the touch trace in area C of FIG. 2. In some embodiments of the present disclosure, the touch trace 306 further includes at least one second extension section 330 extending in a third direction, the second extension section 330 connects two adjacent first extension sections 310, and the third direction is not parallel to the first direction Y and the second direction X. The second extension section 330 is distributed in at least two conductive layers and portions of the second extension section 330 distributed in different conductive layers are connected through a via-hole in the first insulation layer. A line width of the second extension section 330 is greater than a line width of an area of the first extension section 310 not provided to correspond to the via-hole. The line width of the second extension section 330 is not less than 10 μm.

As shown in FIGS. 2, 13, and 14, FIG. 13 is a schematic structure diagram of the touch trace in area F of FIG. 2, and FIG. 14 is a schematic structure diagram of the touch trace in area D or E of FIG. 2. In some embodiments of the present disclosure, the touch trace 306 further includes at least one third extension section 340 extending in the first direction Y, the third extension section 340 is distributed in at least two conductive layers, portions of the third extension section 340 distributed in different conductive layers are connected through a via-hole in the first insulation layer, and a line width of an area of the third extension section 340 provided to correspond to the via-hole is greater than a line width of an area of the third extension section 340 not provided to correspond to the via-hole. By way of example, the line width of the area of the third extension section 340 provided to correspond to the via-hole is not less than 10 μm, and the line width of the area of the third extension section 340 not provided to correspond to the via-hole is greater than or equal to 3 μm and less than 10 μm.

A single touch trace 306 may include a plurality of third extension sections 340, and different third extension sections 340 may be distributed at different locations on the base substrate 100. As shown in FIGS. 2 and 14, in some embodiments of the present disclosure, the at least one third extension section 340 includes at least one second guiding section 346, the second guiding section 346 is provided in the first trace area 121 or the second trace area 122, and the second guiding section 346 is not in direct contact with the touch electrode. The second guiding section 346 includes at least one fourth via-hole area 347 and at least one fourth connection area 348 connected to each other, the fourth via-hole area 347 is provided to correspond to the via-hole, and a line width of the fourth via-hole area 347 is greater than a line width of the fourth connection area 348. A spacing between an outer edge of the fourth via-hole area 347 and an edge of the via-hole within the fourth via-hole area 347 is not less than 2.5 μm.

Further, each of the fourth via-hole area 347 and the fourth connection area 348 has a first side close to the touch electrode and a second side away from the touch electrode. There is a first spacing between the first side of the fourth via-hole area 347 and the first side of the fourth connection area 348, and there is a second spacing between the second side of the fourth via-hole area 347 and the second side of the fourth connection area 348. In an embodiment, each of the first spacing and the second spacing is greater than 0 and the difference between the first spacing and the second spacing is not greater than 1 μm, preferably, the first spacing and the second spacing are substantially equal. Of course, the structure of the second guiding section 346 may also be designed with reference to the structure of the first guiding section 316 in FIGS. 8 and 9, which will not be described in detail herein.

As shown in FIGS. 2 and 14, the second guiding sections 346 of different touch traces 306 are spaced apart in the second direction X, and the fourth via-hole areas 347 of the second guiding sections 346 of two adjacent touch traces 306 are staggered. Further, the spacing in the second direction X between the fourth via-hole areas 347 of the second guiding sections 346 of the two adjacent touch traces 306 is less than the spacing in the second direction X between the fourth connection areas 348 of the second guiding sections of the two adjacent touch traces 306. For example, if the spacing in the second direction X between the fourth connection areas 348 of the second guiding sections 346 of the two adjacent touch traces 306 is 3 μm, the spacing in the second direction X between the fourth via-hole areas 347 of the second guiding sections 346 of the two adjacent touch traces 306 may be less than 3 μm because the fourth via-hole areas 347 are staggered, which is conducive to reducing the space occupied by the arrangement of the plurality of touch traces 306 in the second direction X and thus reducing the width of the second trace area 122, thereby achieving a narrower bezel design.

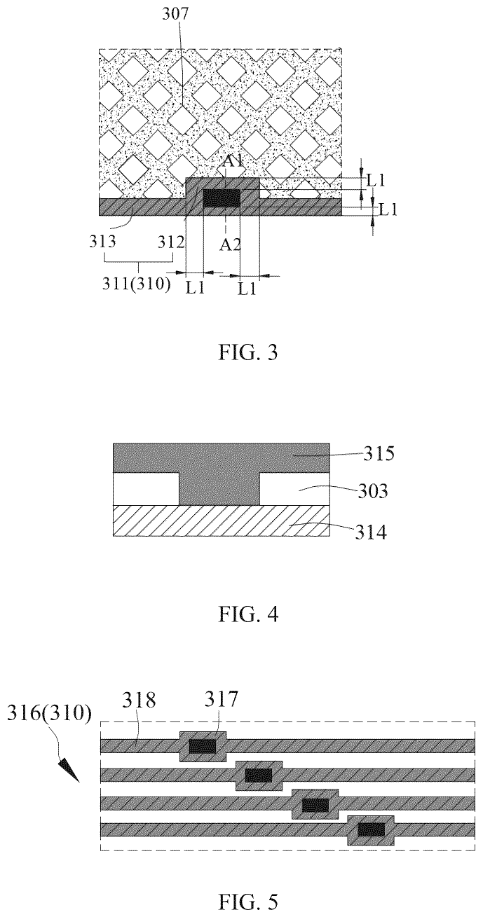

The touch trace 306 may be connected to the first electrode group 070 and the second electrode group 080. As shown in FIGS. 2 and 3, in some embodiments, the touch trace 306 is connected to the first electrode group 070, the at least one first extension section 310 includes a first electrode-connecting section 311, and the first electrode-connecting section 311 is in contact with and is connected to the touch electrode. The first electrode-connecting section 311 includes at least one first via-hole area 312 and at least one first connection area 313 connected to each other, and the first via-hole area 312 is provided to correspond to the via-hole, and a line width of the first via-hole area 312 is greater than a line width of the first connection area 313. A spacing L1 between an outer edge of the first via-hole area 312 and an edge of the via-hole within the first via-hole area 312 is not less than 2.5 μm. The touch trace 306 is in contact with and is connected to the first touch electrode 307 via the first electrode-connecting section 311.

Each of the first via-hole area 312 and the first connection area 313 has a first side close to the touch electrode and a second side away from the touch electrode, and the second side of the first via-hole area 312 is flush with the second side of the first connection area 313. In this way, a portion of the first via-hole area 312 may be provided in the touch area 110, thereby reducing the space occupied by the touch trace 306 in the first trace area 121 and providing a structural basis for reducing the width of the first trace area 121.

As shown in FIGS. 3 and 4, FIG. 4 is a cross-sectional view of FIG. 3 taken along A1-A2. Further, the first electrode-connecting section 311 includes a first connection sub-section 314 and a second connection sub-section 315, the first connection sub-section 314 is distributed in the first conductive layer 301, and the second connection sub-section 315 is distributed in the second conductive layer 302. One of the first connection sub-section 314 and the second connection sub-section 315 is distributed in the same conductive layer as the first touch electrode 307 and is in direct contact with the first touch electrode 307. The orthographic projection of the first sub-connecting section 314 on the substrate 100 and the orthographic projection of the second sub-connecting section 315 on the substrate 100 are at least partially overlapped, and furthermore, the overlapping ratio of the orthographic projection of the first sub-connecting section 314 on the base substrate 100 and the orthographic projection of the second sub-connecting section 315 on the base substrate 100 is not less than 90%.

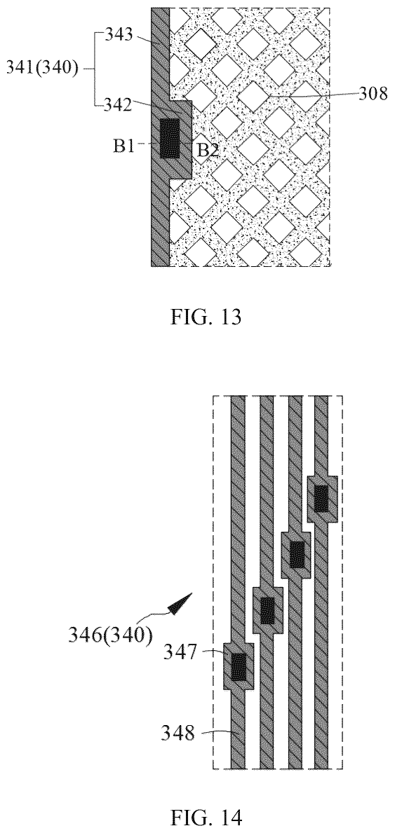

As shown in FIGS. 2 and 13, in some other embodiments, the touch trace 306 is connected to the second electrode group 080, the at least one third extension section 340 includes a second electrode-connecting section 341, the second electrode-connecting section 341 is provided in the second trace area 122, and the touch trace 306 is in contact with and is connected to the second electrode group 080 via the second electrode-connecting section 341. The second electrode-connecting section 341 includes at least one third via-hole area 342 and at least one third connection area 343 connected to each other, the third via-hole area 342 is provided to correspond to the via-hole, and a line width of the third via-hole area 342 is greater than a line width of the third connection area 343. A spacing between an outer edge of the third via-hole area 342 and an edge of the via-hole within that third via-hole area 342 is not less than 2.5 μm.

Each of the third via-hole area 342 and the third connection area 343 has a first side close to the second electrode group 080 and a second side away from the second electrode group 080, and the second side of the third via-hole area 342 is flush with the second side of the third connection area 343. In this way, a portion of the third via-hole area 342 may be provided in the touch area 110, thereby reducing the space occupied by the touch trace 306 in the second trace area 122 and providing a structural basis for reducing the width of the second trace area 122.

Further, as shown in FIG. 16, the second electrode-connecting section 341 includes a third connection sub-section 344 and a fourth connection sub-section 345, the third connection sub-section 344 is distributed in the first conductive layer 301, the fourth connection sub-section 345 is distributed in the second conductive layer 302, and one of the third connection sub-section 344 and the fourth connection sub-section 345 is distributed in the same conductive layer as the second touch electrode 308 and is in direct contact with the second touch electrode 308. An orthographic projection of the third connection sub-section 344 on the base substrate 100 and an orthographic projection of the fourth connection sub-section 345 on the base substrate 100 are at least partially overlapped, and further, the overlapping ratio of the orthographic projection of the third connection sub-section 344 on the base substrate 100 and the orthographic projection of the fourth connection sub-section 345 on the base substrate 100 is not less than 90%.

The touch layer 300 may also include a protective layer 305, and the protective layer 305 is provided on a side of the second conductive layer 302 away from the base substrate 100.

As shown in FIG. 15, in some embodiments of the present disclosure, the touch display panel further includes a driving circuit layer, a light-emitting layer, and an encapsulation layer 230 provided between the base substrate 100 and the touch layer 300. The driving circuit layer includes a plurality of pixel circuits, and the light-emitting layer is provided on the side of the driving circuit layer away from the base substrate 100. The light-emitting layer includes a plurality of light-emitting elements, and the pixel circuits are used to drive the light-emitting elements in a one-to-one correspondence manner to emit light. The encapsulation layer 230 covers the side of the light-emitting layer away from the base substrate 100.

By taking the transistor in the driving circuit being a top-gate thin film transistor as an example, the driving circuit layer includes an active layer 216, a first gate insulation layer 217, a first gate metal layer 218, a second gate insulation layer 219, an interlayer dielectric layer 221, a first source-drain layer 222, a first planarization layer 223, a second source-drain layer 224, and a second planarization layer 225.

The active layer 216 is provided on a side of the base substrate 100; the first gate insulation layer 217 is provided on a side of the active layer 216 away from the base substrate 100, and covers the active layer 216; and the first gate metal layer 218 is provided on a side of the first gate insulation layer 217 away from the base substrate 100, and may include a gate of a transistor and a first electrode plate of a capacitor. The second gate insulation layer 219 is provided on a side of the first gate insulation layer 218 away from the base substrate 100, and covers the first gate metal layer 218; the second gate metal layer 220 is provided on a side of the second gate insulation layer 219 away from the base substrate 100, and may include a second electrode plate of the capacitor; the interlayer dielectric layer 221 is provided on a side of the second gate insulation layer 219 away from the base substrate 100; the first source-drain layer 222 is provided on a side of the interlayer dielectric layer 221 away from the base substrate 100, and includes a source electrode and a drain electrode of the transistor which are connected to the active layer 216. The first planarization layer 223 is provided on a side of the first source-drain layer 222 away from the base substrate 100; the second source-drain layer 224 is provided on a side of the first planarization layer 223 away from the base substrate 100; and the second planarization layer 225 is provided on a side of the second source-drain layer 224 away from the base substrate 100. Further, the driving circuit layer further include a light-shielding layer 215 provided between the base substrate 100 and the active layer 216.

The light-emitting layer is provided on a side of the driving circuit layer away from the base substrate 100. The light-emitting layer further includes a pixel definition layer 229 which separates the plurality of light emitting elements.

The pixel definition layer 229 is provided on a side of the driving circuit layer away from the base substrate 100. The pixel definition layer 229 includes a plurality of pixel openings, each of which defines a range of one light emitting element. The shape of the pixel opening, i.e., the shape of the contour of the orthographic projection of the pixel opening on the base substrate 100, may be a polygon, a smooth closed curve, or other shapes, which is not specifically limited herein. Further, the mesh-opening of the mesh-shaped touch electrode corresponds to the pixel opening to avoid blocking the light emitted by the light emitting element.

By taking the light-emitting element being an OLED light-emitting element as an example, the light-emitting element includes a first electrode layer 226, a light-emitting function layer 227, and a second electrode layer 228 sequentially provided in a direction away from the base substrate 100. The first electrode layer 226 may be used as an anode layer of the light-emitting element. The light-emitting function layer 227 covers the first electrode layer 226, and the second electrode layer 228 covers the light-emitting function layer 227. The first electrode layer 226 may be connected to a source/drain electrode of the transistor. The second electrode layer 228 may cover the light-emitting function layer 227, and may serve as a cathode layer of the light-emitting element, and the second electrode layer 228 may be a single-layer or a multilayer structure, and the material thereof may include one or more of a conductive metal, a metal oxide, and an alloy. The light-emitting function layer 227 is at least partially provided within the pixel opening, may include a hole injection layer, a hole transport layer, a light-emitting material layer, an electron transport layer, and an electron injection layer sequentially laminated in a direction away from the base substrate 100, and may be used to generate visible light by causing the hole and electron to be combined in the light-emitting material layer to form an exciton, and radiating a photon from the exciton, and the specific light-emitting principle thereof will not be described herein in detail.

The encapsulation layer 230 is provided on a side of the light-emitting layer away from the base substrate 100, and may be used to protect the light-emitting layer and block the external water and oxygen from eroding the light-emitting element. In some implementations of the present disclosure, a thin-film encapsulation (TFE) may be used to achieve encapsulation, specifically, the encapsulation layer 230 may include a first inorganic layer, an organic layer, and a second inorganic layer, in which the first inorganic layer covers a surface of the light-emitting layer away from the base substrate 100, the organic layer may be provided on a surface of the first inorganic layer away from the base substrate 100, and has a boundary limited within a boundary of the first inorganic layer, and the second inorganic layer covers the organic layer and a portion of the first inorganic layer not covered by the organic layer. Water-oxygen intrusion may be blocked by the second inorganic layer, and planarization may be achieved by the organic layer having flexibility. The touch layer 300 is provided on a side of the encapsulation layer 230 away from the base substrate 100. The touch layer 300 further includes a second insulation layer 304, and the second insulation layer 304 is provided between the encapsulation layer 230 and the first conductive layer 301.

As shown in FIGS. 1, 2, and 15, the present disclosure also provides a method of fabricating a touch display panel, including:
providing a base substrate 100, the base substrate 100 including a touch area 110, a first trace area 121, and a binding area 123, the binding area 123 being located at a side of the touch area 110 in a first direction Y, and the first trace area 121 being located between the touch area 110 and the binding area 123;
forming a touch layer 300 on a side of the base substrate 100, the touch layer 300 including at least two conductive layers stacked on each other and a first insulation layer 303 provided between two adjacent conductive layers, the touch layer 300 also including a plurality of touch electrodes and a plurality of touch traces 306, the touch electrode being distributed in the conductive layer and located in the touch area 110, an end of the touch trace 306 being connected to the touch electrode, and the other end thereof extending to the binding area 123, the touch trace 306 being at least partially located in the first trace area 121, the touch trace 306 being distributed in at least two conductive layers, and orthographic projections of portions of the touch trace 306 distributed in different conductive layers on the base substrate 100 being at least partially overlapped.

The touch trace 306 includes at least one first extension section 310 extending in a second direction X intersecting the first direction Y, the first extension section 310 is distributed in the at least two conductive layers, portions of the first extension section 310 distributed in different conductive layers are connected through a via-hole in the first insulation layer 303, and a line width of an area of the first extension section 310 provided to correspond to the via-hole is greater than a line width of an area of the first extension section 310 not provided to correspond to the via-hole.

The present disclosure also provides a display device including the above-described touch display panel, which may be a touch display panel of any of the above-described implementations, and the specific structure and beneficial effects thereof may be referred to the above-described implementation of the display panel, which will not be repeated herein. The display device of the present disclosure may be an electronic device such as a mobile phone, a tablet computer, a television, and so on, which will not be enumerated herein.

It is to be noted that although the various steps of the method in the present disclosure are depicted in the accompanying drawings in a particular order, which does not require or imply that the steps must be performed in that particular order or that all of the steps shown must be performed in order to achieve the desired result. Additionally or alternatively, certain steps may be omitted, a plurality of steps may be combined into a single step to be performed, and/or a single step may be divided into a plurality of steps to be performed or the like, all of which should be considered part of the present disclosure.

It is to be understood that the application of the present disclosure is not limited to the detailed structure and arrangement of the components presented herein. The present disclosure may have other implementations and may be realized and performed in a variety of ways. The variations and modifications of the above description fall within the scope of the present disclosure. It is to be understood that the present disclosure as disclosed and limited in this specification extends to all alternative combinations of two or more individual features mentioned or apparent in the text and/or in the accompanying drawings. All of these different combinations constitute a plurality of alternative aspects of the present disclosure. The implementation of this specification illustrates the best way known for implementing the present disclosure and will enable a person skilled in the art to utilize the present disclosure.

What is claimed is:

1. A touch display panel, comprising:
a base substrate, comprising a touch area, a first trace area and a binding area, the binding area being located at a side of the touch area in a first direction, and the first trace area being located between the touch area and the binding area; and
a touch layer, provided on a side of the base substrate, and comprising at least two conductive layers stacked on each other and a first insulation layer provided between two adjacent conductive layers, the touch layer further comprising a plurality of touch electrodes and a plurality of touch traces, the touch electrodes being distributed in the conductive layers and located in the touch area, one end of the touch trace being connected to the touch electrode, another end of the touch trace being extended to the binding area, at least a portion of the touch trace being located in the first trace area, the touch trace being distributed in the at least two conductive layers, and orthographic projections, on the base substrate, of portions of the touch trace distributed in different conductive layers being at least partially overlapped with each other,
wherein the touch trace comprises at least one first extension section extending in a second direction intersecting the first direction, the first extension section is distributed in the at least two conductive layers, portions of the first extension section distributed in different conductive layers are connected through a via-hole in the first insulation layer, and a line width of an area of the first extension section provided to correspond to the via-hole is greater than a line width of an area of the first extension section not provided to correspond to the via-hole.

2. The touch display panel according to claim 1, wherein the at least one first extension section comprises a first electrode-connecting section, and the first electrode-connecting section is in contact with and is connected to the touch electrode, and
the first electrode-connecting section comprises at least one first via-hole area and at least one first connection area connected to each other, and the first via-hole area is provided to correspond to the via-hole, and a line width of the first via-hole area is greater than a line width of the first connection area.

3. The touch display panel according to claim 2, wherein each of the first via-hole area and the first connection area has a first side close to the touch electrode and a second side away from the touch electrode, and the second side of the first via-hole area is flush with the second side of the first connection area.

4. The touch display panel according to claim 2, wherein a spacing between an outer edge of the first via-hole area and an edge of the via-hole within the first via-hole area is not less than 2.5 μm.

5. The touch display panel according to claim 2, wherein the plurality of touch electrodes comprises a plurality of first touch electrodes and a plurality of second touch electrodes, and the plurality of first touch electrodes and the plurality of second touch electrodes are spaced apart and arranged in an array,
the plurality of the first touch electrodes are arranged in the first direction and connected to each other to form a first electrode group, and the plurality of the second touch electrodes are arranged in the second direction and connected to each other to form a second electrode group, and
the touch trace is in contact with and is connected to the first touch electrode group through the first electrode-connecting section.

6. The touch display panel according to claim 1, wherein the at least one first extension section comprises at least one first guiding section, and the first guiding section is located in the first trace area and is not in direct contact with the touch electrode, and
the first guiding section comprises at least one second via-hole area and at least one second connection area connected to each other, the second via-hole area is provided to correspond to the via-hole, and a line width of the second via-hole area is greater than a line width of the second connection area.

7. The touch display panel according to claim 6, wherein the first guiding sections of different touch traces are spaced apart in the first direction, and the second via-hole areas of the first guiding sections of two adjacent touch traces are staggered.

8. The touch display panel according to claim 6, wherein the at least two conductive layers comprise a first conductive layer and a second conductive layer, and the second conductive layer is provided on a side of the first conductive layer away from the base substrate,
the first guiding section comprises a first sub-section and a second sub-section spaced apart and connected in sequence, the first sub-section is distributed in the first conductive layer, and the second sub-section is distributed in the second conductive layer,
each of the first sub-section and the second sub-section has the second via-hole area and the second connection area, and
orthographic projections, on the base substrate, of the second via-hole area of the first sub-section and the second via-hole area of the second sub-section adjacent to the first sub-section are at least partially overlapped, and orthographic projections, on the base substrate, of the second connection area of the first sub-section and the second connection area of the second sub-section are not overlapped.

9. The touch display panel according to claim 6, wherein the at least two conductive layers comprise a first conductive layer and a second conductive layer, and the second conductive layer is provided on a side of the first conductive layer away from the base substrate,
the first guiding section comprises a first sub-section and a second sub-section, the first sub-section is distributed in the first conductive layer, and the second sub-section is distributed in the second conductive layer,
the first sub-section and the second sub-section are both continuous conductive wires, and
orthographic projections of the first sub-section and the second sub-section on the base substrate are at least partially overlapped.

10. The touch display panel according to claim 6, wherein each of the second via-hole area and the second connection area has a first side close to the touch electrode and a second side away from the touch electrode,
the first side of the second via-hole area and the first side of the second connection area have a first spacing therebetween, the second side of the second via-hole area and the second side of the second connection area have a second spacing therebetween, each of the first spacing and the second spacing is greater than 0, and a difference between the first spacing and the second spacing is not greater than 1 μm.

11. The touch display panel according to claim 6, wherein a spacing between an outer edge of the second via-hole area and an edge of the via-hole within the second via-hole area is not less than 2.5 μm.

12. The touch display panel according to claim 1, wherein the touch trace further comprises at least one second extension section extending in a third direction, the second extension section connects two adjacent first extension sections, and the third direction is not parallel to the first direction and the second direction, and
the second extension section is distributed in the at least two conductive layers, portions of the second extension section distributed in different conductive layers are connected through a via-hole in the first insulation layer, and a line width of the second extension section is greater than the line width of the area of the first extension section not provided to correspond to the via-hole.

13. The touch display panel according to claim 1, wherein the line width of the area of the first extension section provided to correspond to the via-hole is not less than 10 μm, and the line width of the area of the first extension section not provided to correspond to the via-hole is greater than or equal to 3 μm and less than 10 μm.

14. The touch display panel according to claim 1, wherein the base substrate further comprises a second trace area, and the second trace area is located at at least one side of the touch area in the second direction,
wherein the touch trace further comprises at least one third extension section extending in the first direction, the third extension section is distributed in the at least two conductive layers, portions of the third extension section distributed in different conductive layers are connected through a via-hole in the first insulation layer, and a line width of an area of the third extension section provided to correspond to the via-hole is greater than a line width of an area of the third extension section not provided to correspond to the via-hole.

15. The touch display panel according to claim 14, wherein the plurality of touch electrodes comprises a plurality of first touch electrodes and a plurality of second touch electrodes, and the plurality of first touch electrodes and the plurality of second touch electrodes are spaced apart and arranged in an array,
the plurality of the first touch electrodes are arranged in the first direction and connected to each other to form a first electrode group, and the plurality of the second touch electrodes are arranged in the second direction and connected to each other to form a second electrode group,
the at least one third extension section comprises a second electrode-connecting section, the second electrode-connecting section is located in the second trace area, and the touch trace is in contact with and is connected to the second electrode group through the second electrode-connecting section, and
the second electrode-connecting section comprises at least one third via-hole area and at least one third connection area connected to each other, the third via-hole area is provided to correspond to the via-hole, and a line width of the third via-hole area is greater than a line width of the third connection area.

16. The touch display panel according to claim 15, wherein each of the third via-hole area and the third connection area has a first side close to the second electrode group and a second side away from the second electrode group, and the second side of the third via-hole area is flush with the second side of the third connection area.

17. The touch display panel according to claim 14, wherein the at least one third extension section includes at least one second guiding section, the second guiding section is located in the first trace area or the second trace area, and the second guiding section is not in direct contact with the touch electrode,
the second guiding section comprises at least one fourth via-hole area and at least one fourth connection area connected to each other, the fourth via-hole area is provided to correspond to the via-hole, and a line width of the fourth via-hole area is greater than a line width of the fourth connection area, and
the second guiding sections of different touch traces are spaced apart in the second direction, and the fourth via-hole areas of the second guiding sections of two adjacent touch traces are staggered.

18. The touch display panel according to claim 1, wherein the touch electrode is mesh-shaped.

19. The touch display panel according to claim 1, wherein the touch display panel further comprises a driving circuit layer, a light-emitting layer and an encapsulation layer provided between the base substrate and the touch layer,
the driving circuit layer includes a plurality of pixel circuits, the light-emitting layer is provided on a side of the driving circuit layer away from the base substrate, the light-emitting layer includes a plurality of light-emitting elements, and the pixel circuits are configured to drive the light-emitting elements in one-to-one correspondence to emit light, and
the encapsulation layer covers a side of the light-emitting layer away from the base substrate.

20. A display device comprising the touch display panel according to claim 1.
